(19) United States
(12) Patent Application Publication
(10) Pub. No.: US 2023/0395650 A1
(43) Pub. Date: Dec. 7, 2023

(54) NITRIDE SEMICONDUCTOR DEVICE AND SEMICONDUCTOR PACKAGE

(71) Applicant: ROHM CO., LTD., Kyoto-shi (JP)

(72) Inventor: Hirotaka OTAKE, Kyoto-shi (JP)

(73) Assignee: ROHM CO., LTD., Kyoto-shi (JP)

(21) Appl. No.: 18/203,650

(22) Filed: May 31, 2023

(30) Foreign Application Priority Data
Jun. 7, 2022 (JP) 2022-092248

(51) Int. Cl. H01L 29/06; H01L 29/778; H01L 29/40; H01L 29/43; H01L 29/417; H01L 29/20; H01L 29/423

(52) U.S. Cl. CPC H01L 29/0607; H01L 29/7786; H01L 29/402; H01L 29/432; H01L 29/41775; H01L 29/2003; H01L 29/42316

(57) ABSTRACT

A nitride semiconductor device includes an electron transit layer formed from a nitride semiconductor, an electron supply layer formed on the electron transit layer from a nitride semiconductor having a larger band gap than the electron transit layer, a gate layer formed on the electron supply layer from a nitride semiconductor including an acceptor impurity, a gate electrode formed on the gate layer, and a passivation layer covering the electron supply layer, the gate layer, and the gate electrode and including first and second openings separated in a first direction, the gate layer being disposed therebetween, a source electrode contacting the electron supply layer through the first opening, a drain electrode contacting the electron supply layer through the second opening, and an auxiliary electrode formed above the electron supply layer, directly covered by the passivation layer, and disposed between the gate electrode and the drain electrode in plan view.

### CROSS-REFERENCE TO RELATED APPLICATION

The application claims priority to Japanese Patent Application No. 2022-092248, filed on Jun. 7, 2022, the entire disclosure of which is hereby incorporated by reference in its entirety.

### BACKGROUND

### 1. Field

The following description relates to a nitride semiconductor device and a semiconductor package.

### 2. Description of Related Art

A nitride semiconductor is currently used to produce a high-electron-mobility transistor (HEMT). When an HEMT is used in a power device, the HEMT is required from the viewpoint of being fail-safe to be normally off so that the source-drain current path (channel) is disconnected in a zero bias state.

Japanese Laid-Open Patent Publication No. 2017-73506 discloses a nitride semiconductor device including a first nitride semiconductor layer (electron transit layer) and a second nitride semiconductor layer (electron supply layer) that have different band gaps (Al composition). The second nitride semiconductor layer is formed on the first nitride semiconductor layer to form a heterojunction. As a result, two-dimensional electron gas is generated in the first nitride semiconductor layer in the vicinity of the interface between the first nitride semiconductor layer and the second nitride semiconductor layer. The energy levels of the first nitride semiconductor layer and the second nitride semiconductor layer are raised by an ionized acceptor that is contained in a gallium nitride layer (p-type GaN layer) doped with an acceptor impurity below a gate electrode. As a result, the energy level of the conduction band at the heterojunction interface becomes higher than the Fermi level. Accordingly, when no bias is applied to the gate electrode, the channel formed by the two-dimensional electron gas is disconnected immediately below the gate electrode. This obtains a normally-off HEMT.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In the HEMT, the electrical potential may vary in a region between the gate electrode, which is formed on the p-type GaN layer, and a drain electrode, which is in contact with the electron supply layer. Such variation may adversely affect the properties (e.g., on-resistance, resistance to voltage stress) of the HEMT.

An aspect of the present disclosure is a nitride semiconductor device that includes an electron transit layer formed from a nitride semiconductor, an electron supply layer formed on the electron transit layer, the electron supply layer being formed from a nitride semiconductor having a band gap that is larger than that of the electron transit layer, a gate layer formed on the electron supply layer, the gate layer being formed from a nitride semiconductor including an acceptor impurity, a gate electrode formed on the gate layer, and a passivation layer covering the electron supply layer, the gate layer, and the gate electrode, the passivation layer including a first opening and a second opening separated from each other in a first direction, the gate layer being disposed between the first opening and the second opening, a source electrode in contact with the electron supply layer through the first opening, a drain electrode in contact with the electron supply layer through the second opening, and an auxiliary electrode formed above the electron supply layer and directly covered by the passivation layer. The auxiliary electrode is disposed between the gate electrode and the drain electrode in plan view.

Other features and aspects will be apparent from the following detailed description, the drawings, and the claims.

### BRIEF DESCRIPTION OF THE DRAWINGS

FIG. 1 is a schematic cross-sectional view showing an example of a nitride semiconductor device in a first embodiment.

FIG. 2 is a schematic plan view of the nitride semiconductor device shown in FIG. 1.

FIG. 3 is an enlarged partial view of FIG. 2.

FIG. 4 is a schematic cross-sectional view showing an example of a step for manufacturing the nitride semiconductor device shown in FIG. 1.

FIG. 5 is a schematic cross-sectional view showing a manufacturing step subsequent to the step shown in FIG. 4.

FIG. 6 is a schematic cross-sectional view showing a manufacturing step subsequent to the step shown in FIG. 5.

FIG. 7 is a schematic cross-sectional view showing a manufacturing step subsequent to the step shown in FIG. 6.

FIG. 8 is a schematic cross-sectional view showing a manufacturing step subsequent to the step shown in FIG. 7.

FIG. 9 is a schematic cross-sectional view showing a manufacturing step subsequent to the step shown in FIG. 8.

FIG. 10 is a schematic cross-sectional view showing a manufacturing step subsequent to the step shown in FIG. 9.

FIG. 11 is a schematic cross-sectional view showing a manufacturing step subsequent to the step shown in FIG. 10.

FIG. 12 is a schematic cross-sectional view showing a manufacturing step subsequent to the step shown in FIG. 11.

FIG. 13 is a schematic cross-sectional view showing a manufacturing step subsequent to the step shown in FIG. 12.

FIG. 14 is a schematic cross-sectional view showing a manufacturing step subsequent to the step shown in FIG. 13.

FIG. 15 is a circuit representation of the nitride semiconductor device shown in FIG. 1.

FIG. 16 is a circuit diagram of a semiconductor package using the nitride semiconductor device.

FIG. 17 is a schematic cross-sectional view of an example of a nitride semiconductor device showing a modified example of a field plate electrode.

FIG. 18 is a schematic cross-sectional view showing an example of a nitride semiconductor device in a second embodiment.

FIG. 19 is a schematic cross-sectional view of an example of a nitride semiconductor device showing a modified example of a gate layer.

FIG. 20 is a schematic cross-sectional view of an example of a nitride semiconductor device showing a modified example of a gate layer.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments of a nitride semiconductor device according to the present disclosure will be described below with reference to the drawings. In the drawings, elements may not be drawn to scale for simplicity and clarity of illustration. In a cross-sectional view, hatching may be partially omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

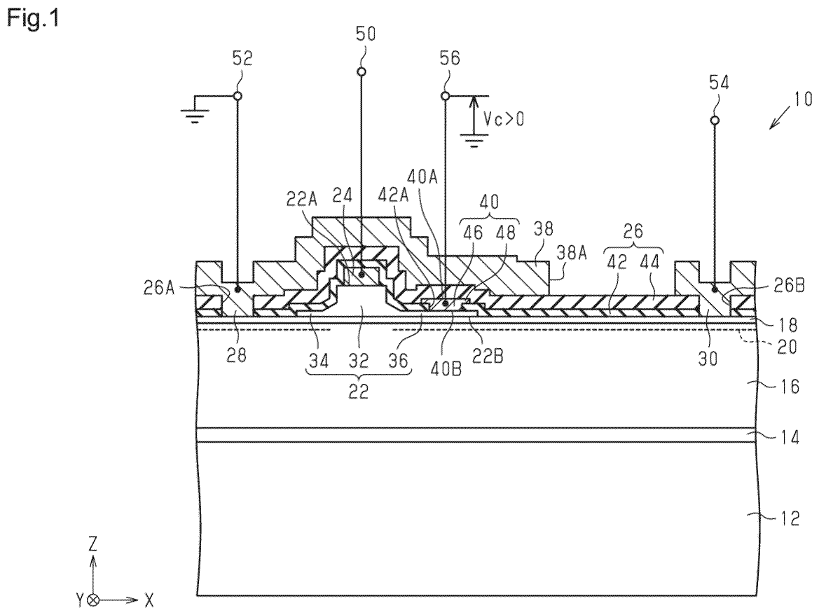

FIG. 1 is a schematic cross-sectional view showing an example of a nitride semiconductor device 10 in a first embodiment. The nitride semiconductor device 10 may include a semiconductor substrate 12 and a buffer layer 14 formed on the semiconductor substrate 12. Among XYZ-axes that are orthogonal to each other shown in FIG. 1, a Z-axis direction is orthogonal to a surface of the semiconductor substrate 12. The term “plan view” used in this specification refers to a view of the nitride semiconductor device 10 in the Z-axis direction from above unless otherwise specifically described. The nitride semiconductor device 10 further includes an electron transit layer 16 and an electron supply layer 18 formed on the electron transit layer 16.

The semiconductor substrate 12 may be formed from silicon (Si), silicon carbide (SiC), GaN, sapphire, or other substrate materials. In an example, the semiconductor substrate 12 may be a Si substrate. The semiconductor substrate 12 may have a thickness that is, for example, greater than or equal to 200 μm and less than or equal to 1500 μm.

The buffer layer 14 may include one or more nitride semiconductor layers. The electron transit layer 16 may be formed on the buffer layer 14. The buffer layer 14 may be formed from any material that limits, for example, bending of the semiconductor substrate 12 caused by a mismatch in thermal expansion coefficient between the semiconductor substrate 12 and the electron transit layer 16, and formation of cracks in the nitride semiconductor device 10. For example, the buffer layer 14 may include at least one of an aluminum nitride (AlN) layer, an aluminum gallium nitride (AlGaN) layer, and a graded AlGaN layer having different aluminum (Al) compositions. For example, the buffer layer 14 may include a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 14 may include a first buffer layer that is an AlN layer formed on the semiconductor substrate 12 and a second buffer layer that is an AlGaN formed on the AlN layer. The first buffer layer may be, for example, an AlN layer having a thickness of 200 nm. The second buffer layer may be formed by stacking a graded AlGaN layer having a thickness of 300 nm a number of times. To inhibit current leakage of the buffer layer 14, a portion of the buffer layer 14 may be doped with an impurity so that the buffer layer 14 becomes semi-insulating. In this case, the impurity is, for example, carbon (C) or iron (Fe). The concentration of the impurity may be, for example, greater than or equal to 4×10¹⁶ cm⁻³.

The electron transit layer 16 is formed from a nitride semiconductor. The electron transit layer 16 may be, for example, a GaN layer. The electron transit layer 16 may have a thickness that is, for example, greater than or equal to 0.5 μm and less than or equal to 2 μm. To inhibit current leakage of the electron transit layer 16, a portion of the electron transit layer 16 may be doped with an impurity so that the electron transit layer 16 excluding an outer layer region becomes semi-insulating. In this case, the impurity may be, for example, C. The concentration of the impurity in the electron transit layer 16 may be, for example, greater than or equal to 4×10¹⁶ cm⁻³. More specifically, the electron transit layer 16 may include GaN layers having different impurity concentrations, for example, a C-doped GaN layer and a non-doped GaN layer. In this case, the C-doped GaN layer may be formed on the buffer layer 14. The C-doped GaN layer may have a thickness that is greater than or equal to 0.3 μm and less than or equal to 2 μm. The C concentration in the C-doped GaN layer may be greater than or equal to 5×10¹⁷ cm⁻³ and less than or equal to 9×10¹⁹ cm⁻³. The non-doped GaN layer may be formed on the C-doped GaN layer and may have a thickness that is greater than or equal to 0.05 μm and less than or equal to 0.4 μm. The non-doped GaN layer is in contact with the electron supply layer 18. In an example, the electron transit layer 16 may include a C-doped GaN layer having a thickness of 0.4 μm and a non-doped GaN layer having a thickness of 0.4 μm. The C concentration in the C-doped GaN layer may be approximately 2×10¹⁹ cm⁻³.

The electron supply layer 18 is formed from a nitride semiconductor having a band gap that is larger than that of the electron transit layer 16. The electron supply layer 18 may be, for example, an AlGaN layer. The band gap increases as the composition of Al increases. Therefore, the electron supply layer 18, which is an AlGaN layer, has a larger band gap than the electron transit layer 16, which is a GaN layer. In an example, the electron supply layer 18 is formed from AlₓGa₁₋ₓN, where 0.1<x<0.4, and more preferably, 0.1<x<0.3. The electron supply layer 18 may have a thickness that is greater than or equal to 5 nm and less than or equal to 20 nm. In an example, the electron supply layer 18 may have a thickness that is greater than or equal to 8 nm.

The electron transit layer 16 and the electron supply layer 18 are formed from nitride semiconductors having different lattice constants. Therefore, the nitride semiconductor forming the electron transit layer 16 (e.g., GaN) and the nitride semiconductor forming the electron supply layer 18 (e.g., AlGaN) form a lattice-mismatching heterojunction. The energy level of the conduction band of the electron transit layer 16 in the vicinity of the heterojunction interface is lower than the Fermi level due to spontaneous polarization of the electron transit layer 16 and the electron supply layer 18 and piezoelectric polarization caused by crystal distortion in the vicinity of the heterojunction interface. As a result, at a location close to the heterojunction interface between the electron transit layer 16 and the electron supply layer 18 (e.g., within range approximately a few nanometers from the interface), two-dimensional electron gas 20 (2DEG) spreads in the electron transit layer 16. The sheet carrier density of the 2DEG 20 formed in the electron transit layer 16 may be increased by increasing at least one of the Al composition and the thickness of the electron supply layer 18.

The nitride semiconductor device 10 further includes a gate layer 22 formed on the electron supply layer 18 and a gate electrode 24 formed on the gate layer 22. The gate layer 22 may be formed on a portion of the electron supply layer 18.

The gate layer 22 is formed from a nitride semiconductor containing an acceptor impurity. In the present embodiment, the gate layer 22 may be a gallium nitride layer (p-type GaN layer) doped with an acceptor impurity. The acceptor impurity may include at least one of zinc (Zn), magnesium (Mg), and carbon (C). The maximum concentration of the acceptor impurity in the gate layer 22 may be greater than or equal to 7×10¹⁸ cm⁻³ and less than or equal to 1×10²⁰ cm⁻³. In an example, the gate layer 22 may be GaN containing at least one of Mg and Zn as an impurity. Further details of the gate layer 22 will be described later.

The gate electrode 24 may be formed of one or more metal layers. In an example, the gate electrode 24 may be formed of a titanium nitride (TiN) layer. In another example, the gate electrode 24 may include a first metal layer formed from Ti and a second metal layer formed from TiN and disposed on the first metal layer. The gate electrode 24 may form a Schottky junction with the gate layer 22. The gate electrode 24 may be formed in a region smaller than the gate layer 22 in plan view. The gate electrode 24 may have a thickness that is, for example, greater than or equal to 50 nm and less than or equal to 200 nm.

The nitride semiconductor device 10 further includes a passivation layer 26 that covers the electron supply layer 18, the gate layer 22, and the gate electrode 24. The passivation layer 26 includes a first opening 26A and a second opening 26B that are separated from each other in an X-axis direction. In this specification, the X-axis direction is also referred to as a first direction, and a Y-axis direction is also referred to as a second direction. Hence, the second direction is orthogonal to the first direction in plan view. The gate layer 22 is disposed between the first opening 26A and the second opening 26B. More specifically, the gate layer 22 may be disposed between the first opening 26A and the second opening 26B at a position closer to the first opening 26A than to the second opening 26B. The passivation layer 26 may be formed from, for example, at least one of silicon nitride (SiN), silicon dioxide (SiO₂), silicon oxynitride (SiON), alumina (Al₂O₃), AlN, and aluminum oxynitride (AlON). The passivation layer 26 may have a thickness that is, for example, greater than or equal to 80 nm and less than or equal to 150 nm.

The nitride semiconductor device 10 further includes a source electrode 28, which is in contact with the electron supply layer18 through the first opening 26A, and a drain electrode 30, which is in contact with the electron supply layer 18 through the second opening 26B. The source electrode 28 and the drain electrode 30 may be formed of one or more metal layers (e.g., any combination of Ti layer, TiN layer, Al layer, AlSiCu layer, AlCu layer, and the like).

At least a portion of the source electrode 28 fills the first opening 26A. This allows the source electrode 28 to be in ohmic contact with the 2DEG 20, which is located immediately below the electron supply layer 18, through the first opening 26A. Also, at least a portion of the drain electrode 30 fills the second openings 26B. This allows the drain electrode 30 to be in ohmic contact with the 2DEG 20, which is located immediately below the electron supply layer 18, through the second opening 26B.

Detail of Gate Layer

The gate layer 22 may include an upper surface 22A on which the gate electrode 24 is formed and a bottom surface 22B that is in contact with the electron supply layer 18. In the example shown in FIG. 1, the gate layer 22 may include a gate ridge 32 that includes the upper surface 22A, and a source-side extension 34 and a drain-side extension 36 that are smaller in thickness than the gate ridge 32. The source-side extension 34 and the drain-side extension 36 extend outward from the gate ridge 32 in plan view.

The source-side extension 34 extends from the gate ridge 32 toward the first opening 26A in plan view. The source-side extension 34 does not reach the first opening 26A. The source-side extension 34 is separated from the source electrode 28 by the passivation layer 26.

The drain-side extension 36 extends from the gate ridge 32 toward the second opening 26B in plan view. The drain-side extension 36 does not reach the second opening 26B. The drain-side extension 36 is separated from the drain electrode 30 by the passivation layer 26.

The gate ridge 32 is disposed between the source-side extension 34 and the drain-side extension 36 and is formed integrally with the source-side extension 34 and the drain-side extension 36. Since the gate layer 22 includes the source-side extension 34 and the drain-side extension 36, the bottom surface 22B is greater in area than the upper surface 22A. In the example shown in FIG. 1, the drain-side extension 36 extends outward from the gate ridge 32 longer than the source-side extension 34 does in plan view. In other words, the drain-side extension 36 is greater in dimension in the X-axis direction than the source-side extension 34. In another example, the source-side extension 34 and the drain-side extension 36 may be the same in dimension in the X-axis direction. The dimension of the source-side extension 34 in the X-axis direction may be, for example, greater than or equal to 0.2 μm and less than or equal to 0.3 μm. The dimension of the drain-side extension 36 in the X-axis direction may be, for example, greater than or equal to 0.5 μm and less than or equal to 1.5 μm. In an example, the dimension of the drain-side extension 36 in the X-axis direction may be greater than or equal to 1 μm.

The gate ridge 32 corresponds to a relatively thick portion of the gate layer 22. The gate ridge 32 may have a thickness that is, for example, greater than or equal to 80 nm and less than or equal to 150 nm. The thickness of the gate ridge 32 may be determined taking into consideration parameters including a gate threshold voltage. In an example, the thickness of the gate ridge 32 may be greater than 110 nm.

Each of the source-side extension 34 and the drain-side extension 36 is smaller in thickness than the gate ridge 32. In an example, the thickness of each of the source-side extension 34 and the drain-side extension 36 may be less than or equal to half of the thickness of the gate ridge 32.

Each of the source-side extension 34 and the drain-side extension 36 may include a flat portion having a substantially constant thickness. As shown in FIG. 1, each of the source-side extension 34 and the drain-side extension 36 may further include an inclined portion having a thickness that gradually decreases as the gate ridge 32 becomes farther. The inclined portion is formed between the gate ridge 32 and the flat portion. In an example, the flat portion of each of the source-side extension 34 and the drain-side extension 36 may have a thickness that is greater than or equal to 5 nm and less than or equal to 25 nm. In this specification, “substantially constant thickness” refers to a thickness within a manufacturing variation range (for example, 20%).

Field Plate Electrode

The nitride semiconductor device 10 may further include a field plate electrode 38 formed on the passivation layer 26. The field plate electrode 38 extends at least partially in a region between the gate layer 22 and the drain electrode 30 in plan view. The field plate electrode 38 is separated from the drain electrode 30. Therefore, the field plate electrode 38 may include an end 38A located between the drain electrode 30 (second opening 26B) and the gate layer 22 in plan view.

The field plate electrode 38 is electrically connected to the source electrode 28. In the example of FIG. 1, the field plate electrode 38 may be continuous with the source electrode 28. In this case, the field plate electrode 38 is formed integrally with the source electrode 28. Of the integrally formed electrodes, the source electrode 28 may include at least the portion that is embedded in the first opening 26A of the passivation layer 26, and the field plate electrode 38 may include the remaining portion.

When a drain voltage is applied to the drain electrode 30 in the zero bias state, in which no gate voltage is applied to the gate electrode 24, the field plate electrode 38 reduces concentration of electric field in the vicinity of an end of the gate electrode 24.

Detail of Auxiliary Electrode

The nitride semiconductor device 10 further includes an auxiliary electrode 40 disposed between the gate layer 22 and the drain electrode 30 in the X-axis direction in plan view. The auxiliary electrode 40 is formed above the electron supply layer 18 and is directly covered by the passivation layer 26. The auxiliary electrode 40 may include an upper surface 40A that is in contact with the passivation layer 26. In the example of FIG. 1, the auxiliary electrode 40 is formed on the drain-side extension 36 of the gate layer 22. Therefore, the auxiliary electrode 40 includes a bottom surface 40B that is in contact with the drain-side extension 36. The nitride semiconductor device 10 may have an operation mode in which the auxiliary electrode 40 is positively biased with respect to the source electrode 28. In an example, the nitride semiconductor device 10 may have an operation mode in which the source electrode 28 is grounded and a voltage V_{c}(>0) is applied to the auxiliary electrode 40.

The auxiliary electrode 40 may be formed of one or more metal layers (e.g., any combination of Ti layer, TiN layer, Al layer, AlSiCu layer, AlCu layer, and the like).

The passivation layer 26 may include a first layer 42 including a third opening 42A and a second layer 44 formed on the first layer 42. The auxiliary electrode 40 includes a base portion 46 embedded in the third opening 42A of the first layer 42 and an upper portion 48 directly covered by the second layer 44. The upper portion 48 is formed in a region greater than the third opening 42A in plan view. In an example, the auxiliary electrode 40 (e.g., the base portion 46) may have a dimension in the X-axis direction that is greater than or equal to 0.4 μm.

In the example of FIG. 1, the auxiliary electrode 40 is electrically insulated from the field plate electrode 38 by the passivation layer 26. More specifically, the auxiliary electrode 40 is separated from the field plate electrode 38 by the second layer 44 of the passivation layer 26.

The second layer 44 of the passivation layer 26 may be greater in thickness than the first layer 42. In an example, when the thickness of the passivation layer 26 is approximately 100 nm, the first layer 42 may be approximately 20 nm and the second layer 44 may be approximately 80 nm.

Electrode Connection Terminal

The nitride semiconductor device 10 may further include a gate terminal 50, a source terminal 52, a drain terminal 54, and a control terminal 56. Each of the terminals 50, 52, 54, and 56 may be formed to be a metal pad or an internal terminal that is connected to a metal pad. The gate terminal 50 is electrically connected to the gate electrode 24. The source terminal 52 is electrically connected to the source electrode 28. The source terminal 52 is also electrically connected to the field plate electrode 38. The drain terminal 54 is electrically connected to the drain electrode 30. The control terminal 56 is electrically connected to the auxiliary electrode 40.

Layout of Nitride Semiconductor Device

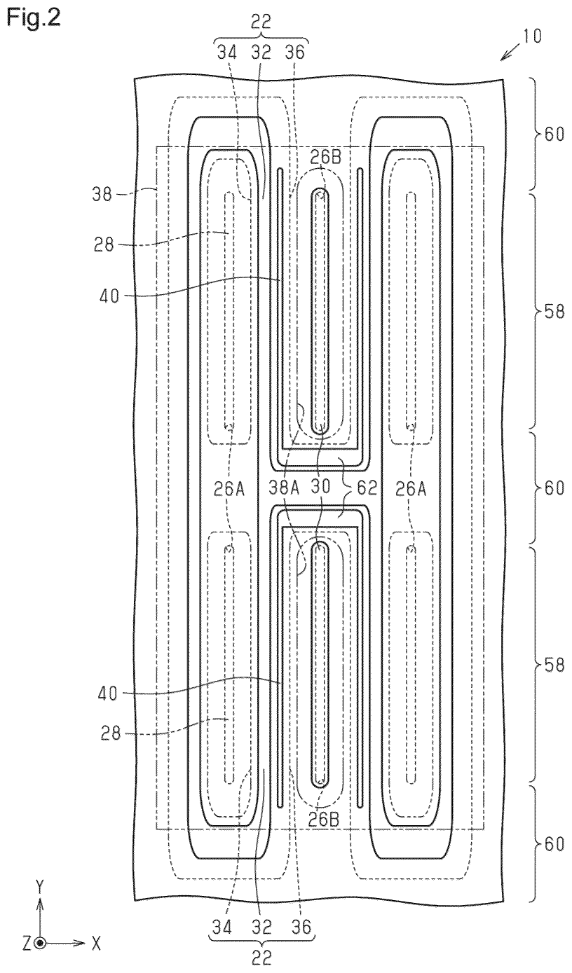

FIG. 2 is a schematic plan view of the nitride semiconductor device 10 shown in FIG. 1. In FIG. 2, the same reference characters are given to those components that are the same as the corresponding components shown in FIG. 1. FIG. 2 does not show the gate electrode 24 to simplify illustration and facilitate understanding. In addition, the source electrode 28, the field plate electrode 38, and the passivation layer 26 are transparently drawn so that the layers underneath are visible. The first opening 26A and the second opening 26B of the passivation layer 26 are indicated by broken lines. In the gate layer 22, the gate ridge 32 is indicated by a solid line, and the source-side extension 34 and the drain-side extension 36 are indicated by broken lines.

As shown in FIG. 2, the nitride semiconductor device 10 includes active regions 58 that contribute to operation of the transistor and inactive regions 60 that do not contribute to operation of the transistor. In the example of FIG. 2, the active regions 58 and the inactive regions 60 are alternately arranged in the Y-axis direction. The drain electrode 30 is formed in each active region 58. The active region 58 may extend in substantially the same range as the drain electrode 30 in the Y-axis direction. The inactive region 60 may extend in a range where the drain electrode 30 does not exist in the Y-axis direction. Therefore, the inactive region 60 is located next to the active region 58 in the Y-axis direction.

In the active region 58, the source electrode 28, the gate layer 22 on which the gate electrode 24 (not shown in FIG. 2) is disposed, and the drain electrode 30 are arranged next to each other in one direction (the X-axis direction in FIG. 2). Thus, the nitride semiconductor device 10 is operated as a HEMT. FIG. 2 shows that, in one active region 58, two first openings 26A are arranged symmetrically in the X-axis direction about the second opening 26B. The auxiliary electrode 40 is disposed on the drain-side extension 36 in the active region 58.

The nitride semiconductor device 10 may further include a connection portion 62 formed in the inactive region 60. The connection portion 62 is electrically connected to the auxiliary electrode 40. As shown in FIG. 2, the auxiliary electrode 40 extending in the Y-axis direction may be joined to the connection portion 62 extending in the X-axis direction. In the same manner as the auxiliary electrode 40, the connection portion 62 is covered by the passivation layer 26.

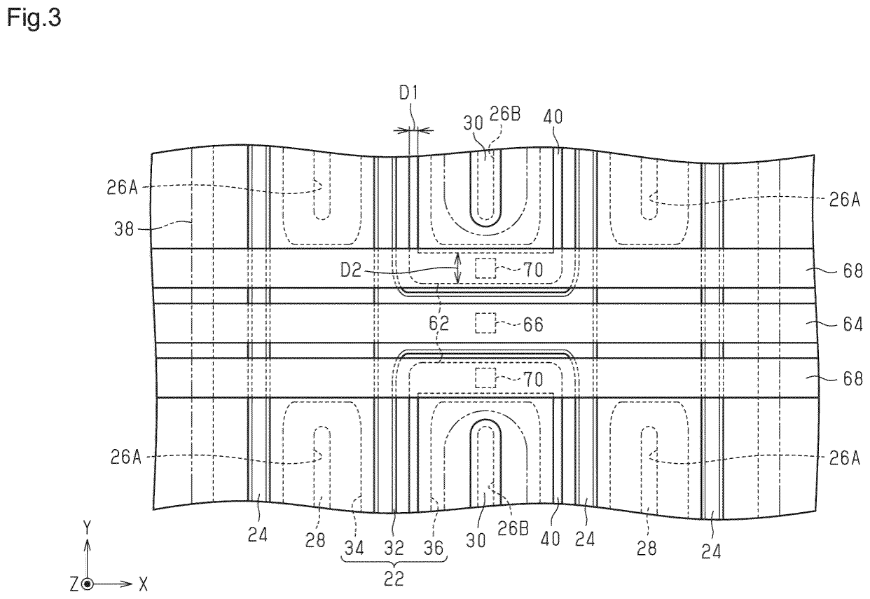

FIG. 3 is an enlarged partial view of FIG. 2. As shown in FIG. 3, the nitride semiconductor device 10 may further include a gate interconnect 64, a via 66 for the gate interconnect 64, a control interconnect 68, and a via 70 for the control interconnect 68.

In the example of FIG. 3, the gate interconnect 64 extends in the X-axis direction. The via 66 is configured to connect the gate interconnect 64 to the gate electrode 24. The via 66 for the gate interconnect may be disposed in a region where the gate interconnect 64 overlaps the gate electrode 24 in plan view. In the example of FIG. 3, the via 66 is separated from the drain electrode 30 in the Y-axis direction. The via 66 may extend in the Z-axis direction through the passivation layer 26 (refer to FIG. 1) and an interlayer insulation layer (not shown) formed on the passivation layer 26. The gate interconnect 64 is electrically connected to the gate terminal 50 (refer to FIG. 1).

The control interconnect 68 may extend substantially parallel to the gate interconnect 64. The via 70 is configured to connect the control interconnect 68 to the connection portion 62. Thus, the auxiliary electrode 40 is connected to the control interconnect 68 by the connection portion 62 and the via 70. The via 70 may be disposed in a region where the control interconnect 68 overlaps the connection portion 62 in plan view. In the example of FIG. 3, the via 70 is separated from the drain electrode 30 in the Y-axis direction. The via 70 may extend in the Z-axis direction through the passivation layer 26 (refer to FIG. 1) and an interlayer insulation layer (not shown) that is formed on the passivation layer 26. The control interconnect 68 is electrically connected to the control terminal 56 (refer to FIG. 1).

A dimension D2 of the connection portion 62 in the Y-axis direction is larger than a dimension D1 of the auxiliary electrode 40 in the X-axis direction. When the dimension D2 of the connection portion 62 in the Y-axis direction is larger than the dimension of the via 70, the connection portion 62 is connectable to the control interconnect 68 without increasing the dimension D1 of the auxiliary electrode 40 in the X-axis direction.

Method for Manufacturing Nitride Semiconductor Device

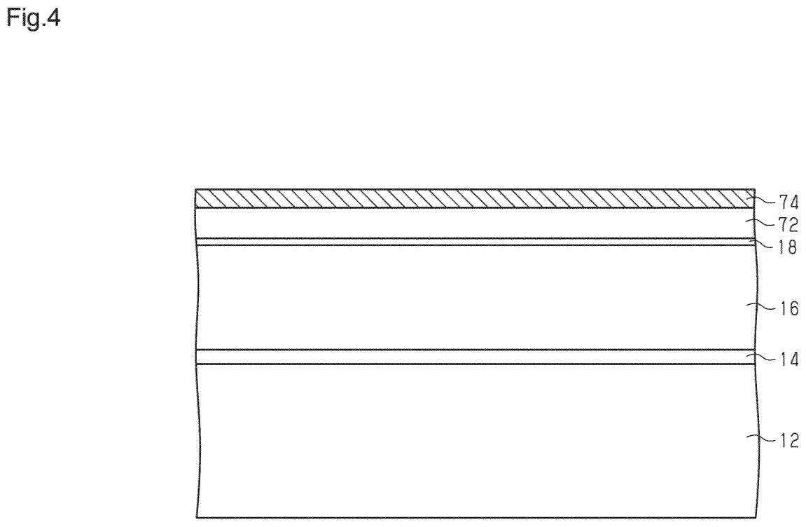

An example of a method for manufacturing the nitride semiconductor device 10 shown in FIG. 1 will be described. FIGS. 4 to 14 are schematic cross-sectional views showing an example of manufacturing steps of the nitride semiconductor device 10. To facilitate understanding, in FIGS. 4 to 14, the same reference characters are given to those components that are the same as the corresponding components shown in FIG. 1.

As shown in FIG. 4, the method for manufacturing the nitride semiconductor device 10 includes sequentially forming the buffer layer 14, the electron transit layer 16, the electron supply layer 18, a gallium nitride (GaN) layer 72, and a metal layer 74 on the semiconductor substrate 12, which is, for example, a Si substrate. Metal organic chemical vapor deposition (MOCVD) may be used to epitaxially grow the buffer layer 14, the electron transit layer 16, the electron supply layer 18, and the GaN layer 72. The metal layer 74 may be formed by, for example, sputtering.

Although not shown in detail, in an example, the buffer layer 14 may be a multilayer buffer layer. The multilayer buffer layer may include an AlN layer (first buffer layer) formed on the semiconductor substrate 12 and a graded AlGaN layer (second buffer layer) formed on the AlN layer. The graded AlGaN layer may be formed, for example, by stacking three AlGaN layers having Al compositions of 75%, 50%, and 25% in the order from the side of the AlN layer.

The electron transit layer 16 formed on the buffer layer 14 may be a GaN layer. The electron supply layer 18 formed on the electron transit layer 16 may be an AlGaN layer. Thus, the electron supply layer 18 is formed from a nitride semiconductor having a band gap that is larger than that of the electron transit layer 16.

The GaN layer 72 formed on the electron supply layer 18 may contain magnesium as an acceptor impurity. The GaN layer 72 that contains an acceptor impurity may be formed by doping the GaN layer 72 with magnesium while the GaN layer 72 is growing on the electron supply layer 18. The amount of magnesium, as a dopant in the GaN layer 72, may be adjusted by controlling, for example, the growth temperature and the flow rate of a doping gas (e.g., biscyclopentadienyl magnesium (Cp₂Mg)) supplied to the growth chamber. In an example, the GaN layer 72 may contain magnesium as an impurity at a concentration that is greater than or equal to 1×10¹⁸ cm⁻³ and less than 1×10²⁰ cm⁻³.

The metal layer 74 may be formed on the GaN layer 72 by, for example, sputtering. In an example, the metal layer 74 may be a TiN layer.

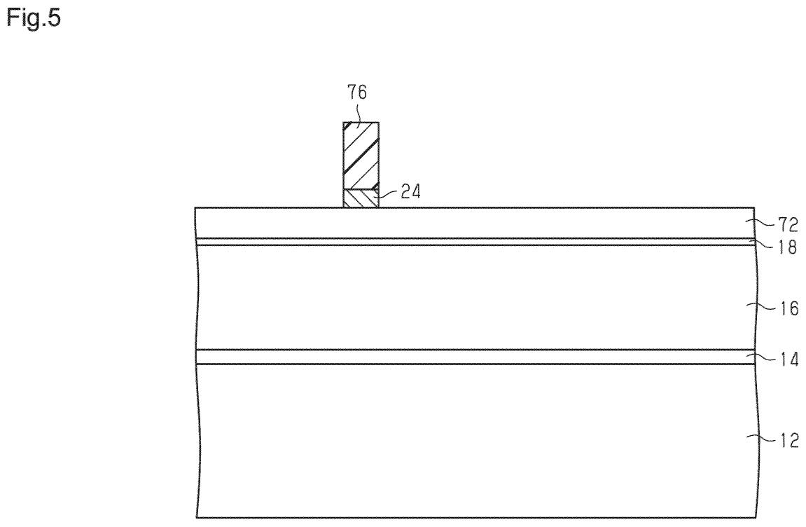

FIG. 5 is a schematic cross-sectional view showing a manufacturing step subsequent to the step shown in FIG. 4. As shown in FIG. 5, the method for manufacturing the nitride semiconductor device 10 further includes selectively removing the metal layer 74 (refer to FIG. 4) by lithography and etching to form the gate electrode 24. In this step, a mask 76 is formed on a portion of the metal layer 74 that will become the gate electrode 24. The mask 76 may be formed by, for example, exposing a photoresist that is applied to the metal layer 74. In another example, the mask 76 may be a hard mask. The metal layer 74 is etched using the mask 76 to remove the portion of the metal layer 74 that is not covered by the mask 76. As a result, the portion of the metal layer 74 covered by the mask 76 remains to from the gate electrode 24. The mask 76 is removed after the etching.

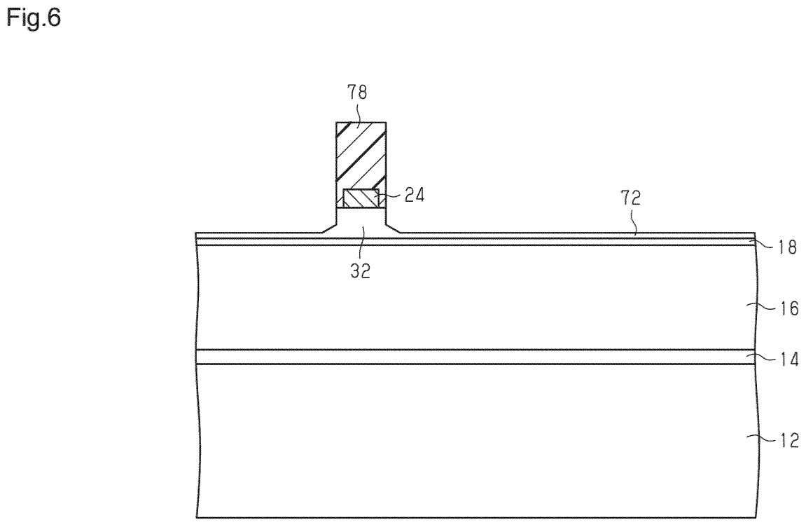

FIG. 6 is a schematic cross-sectional view showing a manufacturing step subsequent to the step shown in FIG. 5. As shown in FIG. 6, the method for manufacturing the nitride semiconductor device 10 further includes selectively removing the GaN layer 72 by lithography and etching to form the gate ridge 32. In this step, the upper surface and the side surfaces of the gate electrode 24 are covered by a mask 78, and the GaN layer 72 is patterned using the mask 78. As a result of the etching, the GaN layer 72 located under the mask 78 remains to form the gate ridge 32 shown in FIG. 1. The portion of the GaN layer 72 that is not covered by the mask 78 is reduced in thickness by etching. In this step, the GaN layer 72 may be etched to have a thickness that gradually decreases as the gate ridge 32 becomes farther in a region adjacent to the gate ridge 32 and a substantially constant thickness in a region located beyond a predetermined distance from the gate ridge 32.

The etching process shown in FIG. 6 may include a number of etching steps performed to obtain a desired shape as described above or a single etching step performed under a condition selected so that the etching speed is decreased in the vicinity of the structure covered by the mask 78. The mask 78 may be a resist mask or a hard mask. For example, the mask 78 may be a hard mask of a SiN film that is formed conformally. The mask 78 is removed after the etching.

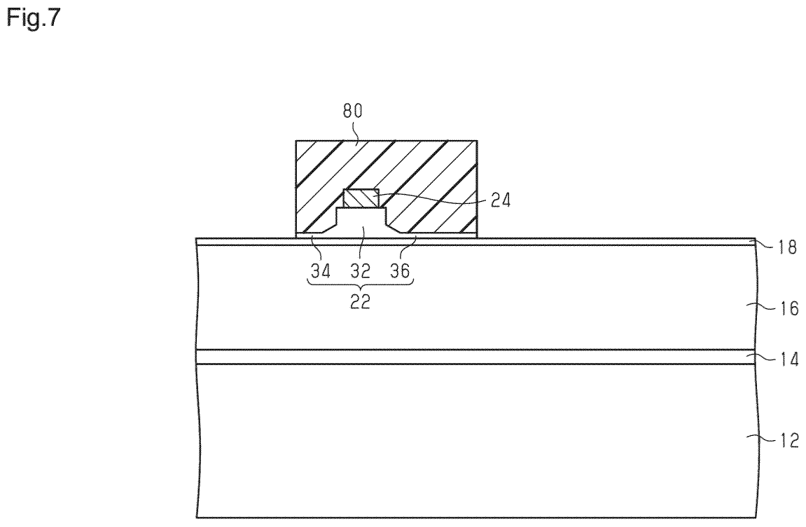

FIG. 7 is a schematic cross-sectional view showing a manufacturing step subsequent to the step shown in FIG. 6. As shown in FIG. 7, the method for manufacturing the nitride semiconductor device 10 further includes selectively removing the GaN layer 72 (refer to FIG. 6) by lithography and etching to form the source-side extension 34 and the drain-side extension 36. In this step, a mask 80 is formed to cover the gate electrode 24, the gate ridge 32, and portions of the GaN layer 72 corresponding to the source-side extension 34 and the drain-side extension 36. Then, the GaN layer 72 is patterned using the mask 80. As a result, the gate layer 22 including the gate ridge 32, the source-side extension 34, and the drain-side extension 36 is formed on the electron supply layer 18. The mask 80 is removed after the etching.

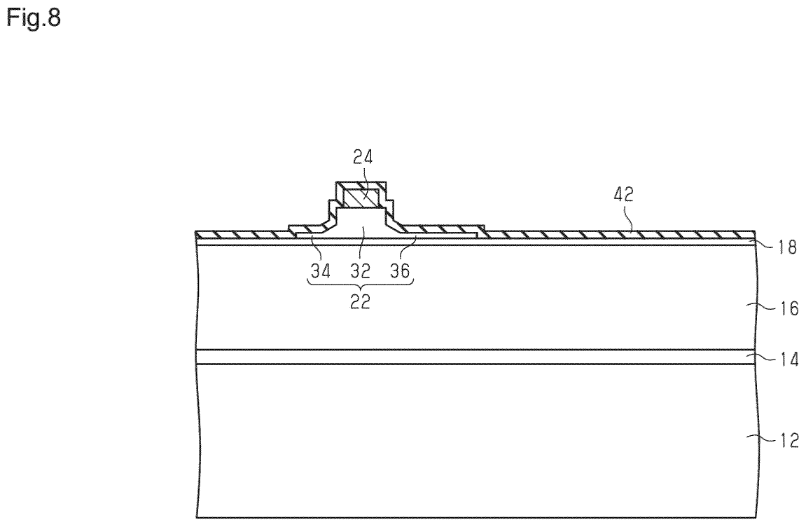

FIG. 8 is a schematic cross-sectional view showing a manufacturing step subsequent to the step shown in FIG. 7. As shown in FIG. 8, the method for manufacturing the nitride semiconductor device 10 further includes forming the first layer 42 of the passivation layer 26 (refer to FIG. 1) to cover the entirety of exposed surfaces of the electron supply layer 18, the gate layer 22, and the gate electrode 24. In an example, the first layer 42 may be a SiN layer formed by low-pressure chemical vapor deposition (LPCVD).

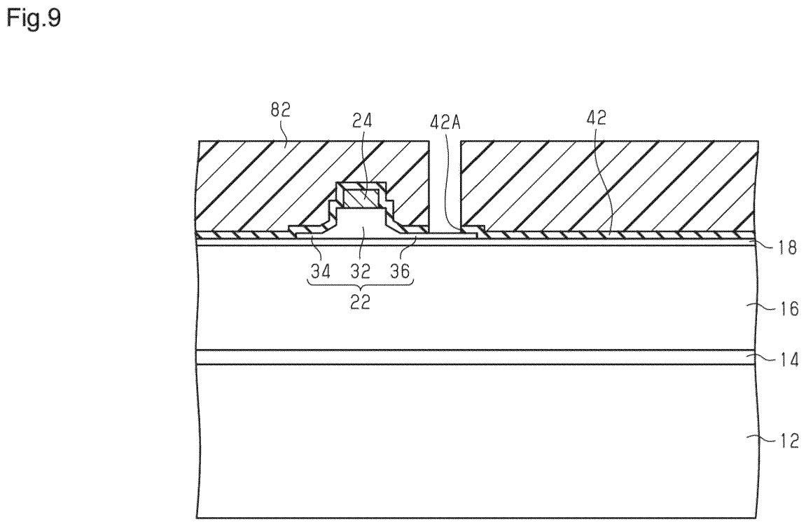

FIG. 9 is a schematic cross-sectional view showing a manufacturing step subsequent to the step shown in FIG. 8. As shown in FIG. 9, the method for manufacturing the nitride semiconductor device 10 further includes selectively removing the first layer 42 by lithography and etching to form the third opening 42A. In this step, a mask 82 is formed to cover the first layer 42 except for the region in which the third opening 42A will be formed, and then the first layer 42 is patterned using the mask 82. As a result, the third opening 42A exposing the drain-side extension 36 is formed. The mask 82 is removed after the etching.

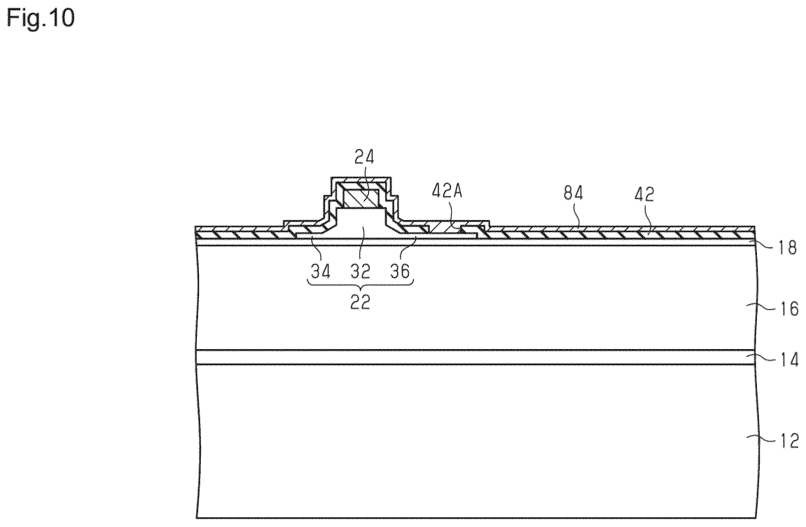

FIG. 10 is a schematic cross-sectional view showing a manufacturing step subsequent to the step shown in FIG. 9. As shown in FIG. 10, the method for manufacturing the nitride semiconductor device 10 further includes forming a metal layer 84 covering the first layer 42. The metal layer 84 is formed to fill the third opening 42A and contact the drain-side extension 36 through the third opening 42A. In an example, the metal layer 84 may include at least one of a Ti layer, a TiN layer, an Al layer, an AlSiCu layer, and an AlCu layer.

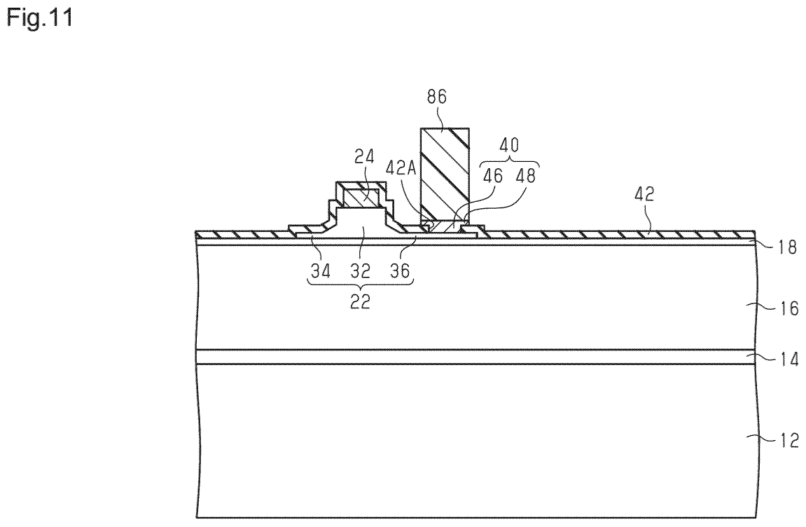

FIG. 11 is a schematic cross-sectional view showing a manufacturing step subsequent to the step shown in FIG. 10. As shown in FIG. 11, the method for manufacturing the nitride semiconductor device 10 further includes selectively removing the metal layer 84 (refer to FIG. 10) by lithography and etching to form the auxiliary electrode 40. In this step, a mask 86 is formed on the portion of the metal layer 84 that will become the auxiliary electrode 40, and then the metal layer 84 is patterned using the mask 86. The mask 86 is formed in a region overlapping the third opening 42A in plan view. The mask 86 may be greater in area than the third opening 42A taking into consideration the margin for alignment with the third opening 42A. As a result, the auxiliary electrode 40 includes the base portion 46 embedded in the third opening 42A of the first layer 42 and the upper portion 48 formed in a region greater than the third opening 42A in plan view. The mask 86 is removed after the etching.

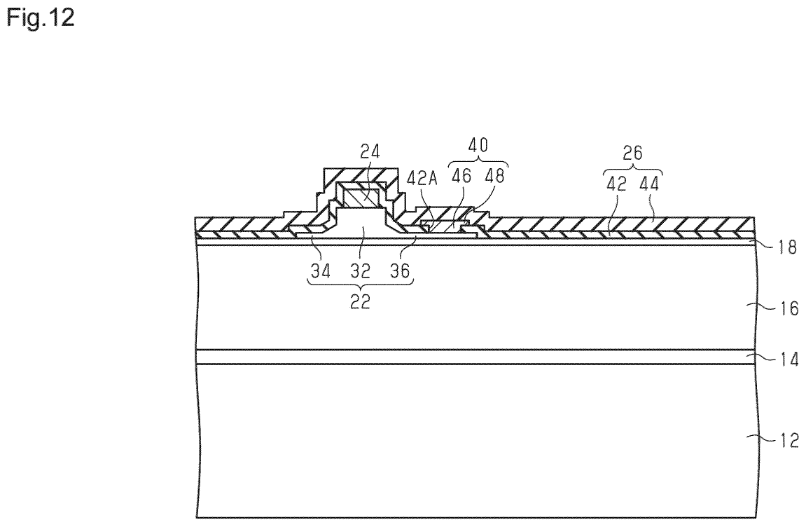

FIG. 12 is a schematic cross-sectional view showing a manufacturing step subsequent to the step shown in FIG. 11. As shown in FIG. 12, the method for manufacturing the nitride semiconductor device 10 further includes forming the second layer 44 on the first layer 42 of the passivation layer 26. In an example, the second layer 44 may be a SiN layer formed by LPCVD.

The second layer 44 of the passivation layer 26 may be greater in thickness than the first layer 42. In an example, when the thickness of the passivation layer 26 is approximately 100 nm, the first layer 42 may be approximately 20 nm and the second layer 44 may be approximately 80 nm.

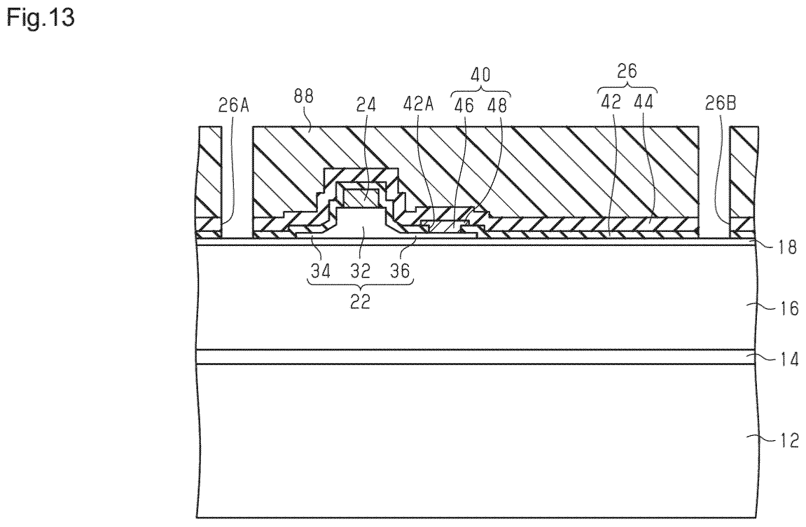

FIG. 13 is a schematic cross-sectional view showing a manufacturing step subsequent to the step shown in FIG. 12. As shown in FIG. 13, the method for manufacturing the nitride semiconductor device 10 further includes selectively removing the passivation layer 26, which includes the first layer 42 and the second layer 44, by lithography and etching to form the first opening 26A and the second opening 26B. In this step, a mask 88 is formed to cover the passivation layer 26 except for regions in which the first opening 26A and the second opening 26B will be formed, and then the passivation layer 26, including the first layer 42 and the second layer 44, is patterned using the mask 88. As a result, the first opening 26A and the second opening 26B, extending through the first layer 42 and the second layer 44 and exposing the electron supply layer 18, are formed. The first opening 26A and the second opening 26B are formed such that the gate layer 22 is located between the first opening 26A and the second opening 26B. The gate layer 22 may be located closer to the first opening 26A than to the second opening 26B. The mask 88 is removed after the etching.

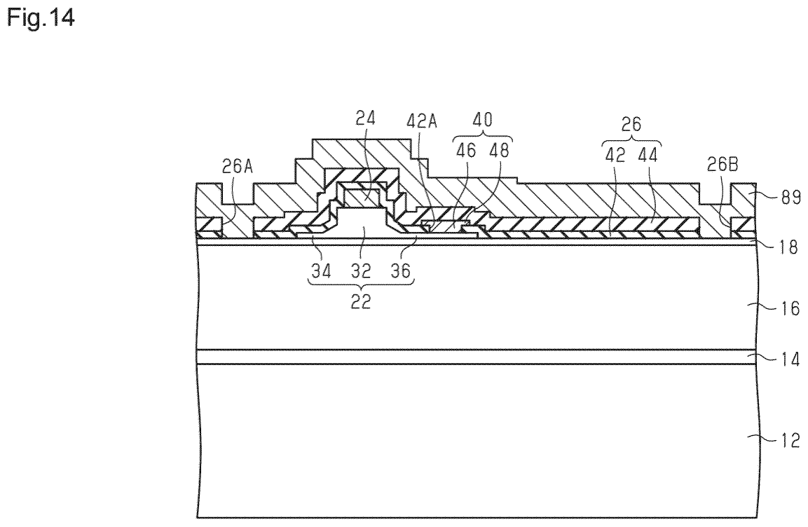

FIG. 14 is a schematic cross-sectional view showing a manufacturing step subsequent to the step shown in FIG. 13. As shown in FIG. 14, the method for manufacturing the nitride semiconductor device 10 further includes forming a metal layer 89 covering the passivation layer 26. The metal layer 89 is formed to fill the first opening 26A and the second opening 26B and contact the electron supply layer 18 through the first opening 26A and the second opening 26B. In an example, the metal layer 89 may include at least one of a Ti layer, a TiN layer, an Al layer, an AlSiCu layer, and an AlCu layer.

The metal layer 89 is selectively removed by lithography and etching to form the source electrode 28, the drain electrode 30, and the field plate electrode 38 shown in FIG. 1. This obtains the nitride semiconductor device 10 shown in FIG. 1.

Half Bridge Module Using Nitride Semiconductor Device

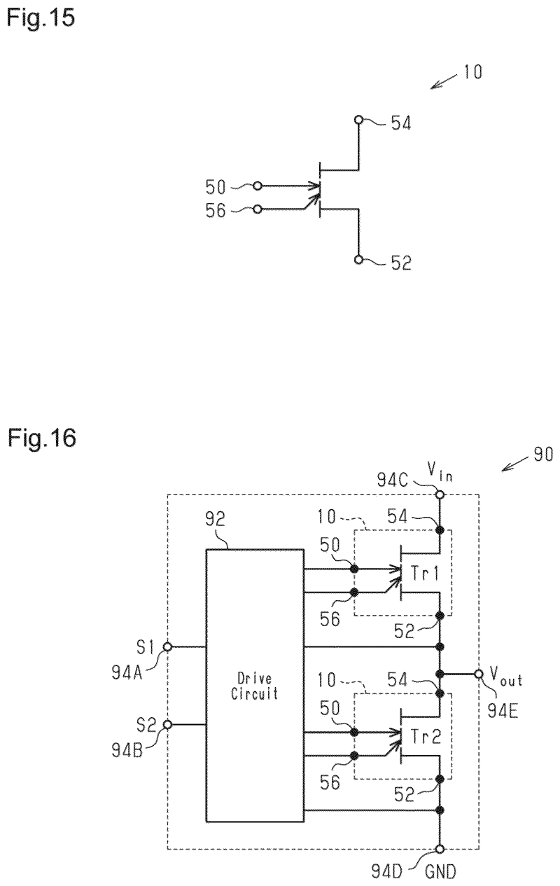

FIG. 15 shows a circuit representation of the nitride semiconductor device 10 shown in FIG. 1. As described above with reference to FIG. 1, the nitride semiconductor device 10 may include the gate terminal 50, the source terminal 52, the drain terminal 54, and the control terminal 56. FIG. 16 is a circuit diagram of a semiconductor package 90 using the nitride semiconductor device 10. The semiconductor package 90 is a half-bridge module in which two nitride semiconductor devices 10 are connected in series. The semiconductor package 90 includes the nitride semiconductor devices 10, a drive circuit 92 connected to the nitride semiconductor devices 10, and external terminals 94A, 94B, 94C, 94D, 94E.

The external terminals 94A and 94B are connected to the drive circuit 92 and are configured to input signals S1 and S2 to the drive circuit 92. The external terminals 94C and 94D correspond to power supply terminals. In an example, voltage yin may be applied to the external terminal 94C, and the external terminal 94D may be grounded. The two nitride semiconductor devices 10 are connected in series between the external terminals 94C and 94D. To distinguish the two nitride semiconductor devices 10, the nitride semiconductor device 10 connected to the external terminal 94C is referred to as a high-side switch Tr1, and the nitride semiconductor device 10 connected to the external terminal 94D is referred to as a low-side switch Tr2. The gate terminal 50 and the control terminal 56 of the high-side switch Tr1 are connected to the drive circuit 92. The gate terminal 50 and the control terminal 56 of the low-side switch Tr2 are connected to the drive circuit 92. The drain terminal 54 of the high-side switch Tr1 is connected to the external terminal 94C. The source terminal 52 of the low-side switch Tr2 is connected to the external terminal 94D. The external terminal 94E is connected to the source terminal 52 of the high-side switch Tr1 and the drain terminal 54 of the low-side switch Tr2 and is configured to output a voltage Vout.

As described above, the control terminals 56 of the nitride semiconductor devices (Tr1, Tr2) are connected to the drive circuit 92 and are not directly connected to any of the external terminals 94A, 94B, 94C, 94D, and 94E. Therefore, even when the nitride semiconductor device 10 includes the auxiliary electrode 40 and the control terminal 56 electrically connected to the auxiliary electrode 40, there is no need to increase the number of external terminals.

Operation

The operation of the nitride semiconductor device 10 of the present embodiment will be described below. When a voltage that is greater than the threshold voltage is applied to the gate electrode 24 of the nitride semiconductor device 10, the 2DEG 20 forms a channel in the electron transit layer 16 and establishes a source-drain connection. In contrast, in the zero bias state, the 2DEG 20 is not formed in at least a portion of the region of the electron transit layer 16 located under the gate layer 22 (refer to FIG. 1). This is because the gate layer 22 contains the acceptor impurity, the energy levels of the electron transit layer 16 and the electron supply layer 18 are raised, and the 2DEG 20 is depleted as a result. This achieves the normally-off operation of the nitride semiconductor device 10.

In the nitride semiconductor device 10, when the source electrode 28 is the reference point and a positive voltage is applied to the drain electrode 30, electrons may be trapped in a region between the gate electrode 24 and the drain electrode 30 (in the present embodiment, in the vicinity of the drain-side extension 36). For example, electrons may be trapped in a defect site (of, for example, the electron supply layer 18) that is formed by processing damage (e.g., etching damage) during the manufacturing of the nitride semiconductor device 10. In addition, when the positive voltage is applied to the drain electrode 30, a potential difference occurs between the gate electrode 24 and the drain electrode 30. As a result, holes may be drawn out of the gate layer 22 from the gate electrode 24. Such electron trapping and hole drawing-out cause variations in the electric potential particularly in the region between the gate electrode 24 and the drain electrode 30. As a result, the gate bias is substantially reduced. This may increase the on-resistance due to, for example, a decrease in the 2DEG 20.

In this regard, the nitride semiconductor device 10 of the present embodiment includes the auxiliary electrode 40, which is formed above the electron supply layer 18 and directly covered by the passivation layer 26. The auxiliary electrode 40 is disposed between the gate electrode 24 and the drain electrode 30 in plan view. The auxiliary electrode 40, disposed between the gate electrode 24 and the drain electrode 30, limits variations in the electric potential in the region between the gate electrode 24 and the drain electrode 30.

As in the present embodiment, in an example of the nitride semiconductor device having an operation mode in which the auxiliary electrode 40 is positively biased with respect to the source electrode 28, while a positive bias (e.g., V_{gs}=5 V) is being applied to the gate electrode 24, holes are injected from the auxiliary electrode 40. This limits variations in the electric potential in the region between the gate electrode 24 and the drain electrode 30. Injection of holes from the auxiliary electrode 40 may compensate for the decrease in the 2DEG 20 and limit variations in the properties (e.g., increase in on-resistance) of the nitride semiconductor device 10.

The nitride semiconductor device 10 of the present embodiment has the following advantages.

(1-1) The nitride semiconductor device 10 includes the auxiliary electrode 40 formed above the electron supply layer 18 and directly covered by the passivation layer 26. The auxiliary electrode 40 is disposed between the gate electrode 24 and the drain electrode 30 in plan view. The auxiliary electrode 40, disposed between the gate electrode 24 and the drain electrode 30, limits variations in the electric potential in the region between the gate electrode 24 and the drain electrode 30.

(1-2) The gate layer 22 may include the gate ridge 32 on which the gate electrode 24 is formed, the source-side extension 34 extending from the gate ridge 32 toward the first opening 26A and being smaller in thickness than the gate ridge 32, and the drain-side extension 36 extending from the gate ridge 32 toward the second opening 26B and being smaller in thickness than the gate ridge 32. The source-side extension 34 and the drain-side extension 36 of the gate layer 22 limit local concentration of electric field in the gate layer 22. This limits occurrence of a gate leakage current, thereby improving the gate breakdown voltage.

(1-3) The auxiliary electrode 40 may include the upper surface 40A in contact with the passivation layer 26 and the bottom surface 40B in contact with the drain-side extension 36. Since the bottom surface 40B of the auxiliary electrode 40 is in contact with the drain-side extensions 36 of the gate layer 22, variations in the electric potential are limited particularly in the vicinity of the drain-side extensions 36.

(1-4) The drain-side extension 36 may be greater in dimension in the first direction (the X-axis direction shown in FIG. 1) than the source-side extension 34. This limits occurrence of gate leakage current in the region, which may receive a relatively large electric field, between the drain electrode 30 and the gate electrode 24.

(1-5) The nitride semiconductor device 10 may have an operation mode in which the auxiliary electrode 40 is positively biased with respect to the source electrode 28. Injection of holes from the auxiliary electrode 40, which is positively biased, limits variations in the electric potential in the region between the gate electrode 24 and the drain electrode 30.

(1-6) The nitride semiconductor device 10 may further include the field plate electrode 38, which is formed on the passivation layer 26 and extends at least partially in the region between the gate layer 22 and the drain electrode 30 in plan view. The field plate electrode 38 is electrically connected to the source electrode 28. Thus, in the zero bias state, in which no gate voltage is applied to the gate electrode 24, when a drain voltage is applied to the drain electrode 30, concentration of electric field in the vicinity of the end of the gate electrode 24 is reduced.

(1-7) The passivation layer 26 may include the first layer 42 including the third opening 42A and the second layer 44 formed on the first layer 42. The auxiliary electrode may include the base portion 46 embedded in the third opening 42A of the first layer 42 and the upper portion 48 directly covered by the second layer 44. The auxiliary electrode may be separated from the field plate electrode 38 by the second layer 44 of the passivation layer 26. The second layer 44 may be greater in thickness than the first layer 42. This reduces parasitic capacitance between the auxiliary electrode 40 and the field plate electrode 38.

(1-8) The nitride semiconductor device 10 may further include the connection portion 62 electrically connected to the auxiliary electrode 40 and formed in the inactive region 60 of the nitride semiconductor device 10. This avoids an increase in the area of the active region 58 for connecting the auxiliary electrode 40.

(1-9) The gate layer 22 is disposed closer to the first opening 26A than to the second opening 26B. Thus, the distance between the gate electrode 24 and the drain electrode 30 is relatively increased, thereby inhibiting dielectric breakdown between the gate and the drain, which are likely to receive a relatively large voltage.

### Modified Example of Field Plate Electrode

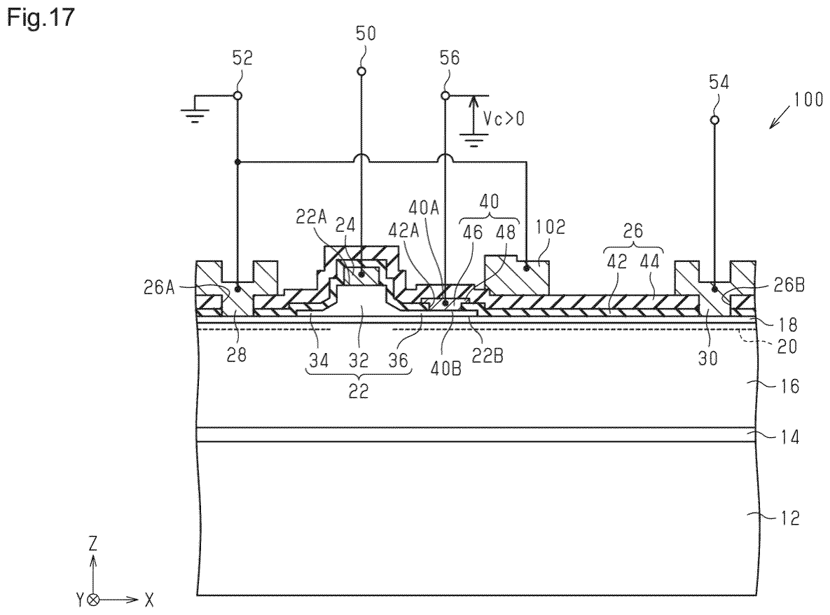

FIG. 17 is a schematic cross-sectional view of an example of a nitride semiconductor device 100 showing a modified example of a field plate electrode. In FIG. 17, the same reference characters are given to those components that are the same as the corresponding components of the nitride semiconductor device 10 shown in FIG. 1. Such components will not be described in detail.

As shown in FIG. 17, the nitride semiconductor device 100 includes a field plate electrode 102. The field plate electrode 102 is separated from the source electrode 28 in the X-axis direction on the passivation layer 26 between the first opening 26A and the second opening 26B. In contrast, the field plate electrode 38 shown in FIG. 1 is continuous with the source electrode 28 on the passivation layer 26 between the first opening 26A and the second opening 26B. Although separated from the source electrode 28, the field plate electrode 102 is electrically connected to the source electrode 28.

The field plate electrode 102 extends at least partially in a region between the gate layer 22 and the drain electrode 30 in plan view, which is similar to the field plate electrode 38. The field plate electrode 102 is disposed between the auxiliary electrode 40 and the drain electrode 30 in plan view. Thus, the field plate electrode 102 is separated from the auxiliary electrode 40 in plan view. Since the upper surface 40A of the auxiliary electrode 40 does not face the field plate electrode 102, the nitride semiconductor device 100 limits an increase in parasitic capacitance between the auxiliary electrode 40 and the field plate electrode 102. In addition, the nitride semiconductor device 100 has advantages similar to the advantages (1-1) to (1-6), (1-8), and (1-9) of the nitride semiconductor device described above.

### Second Embodiment

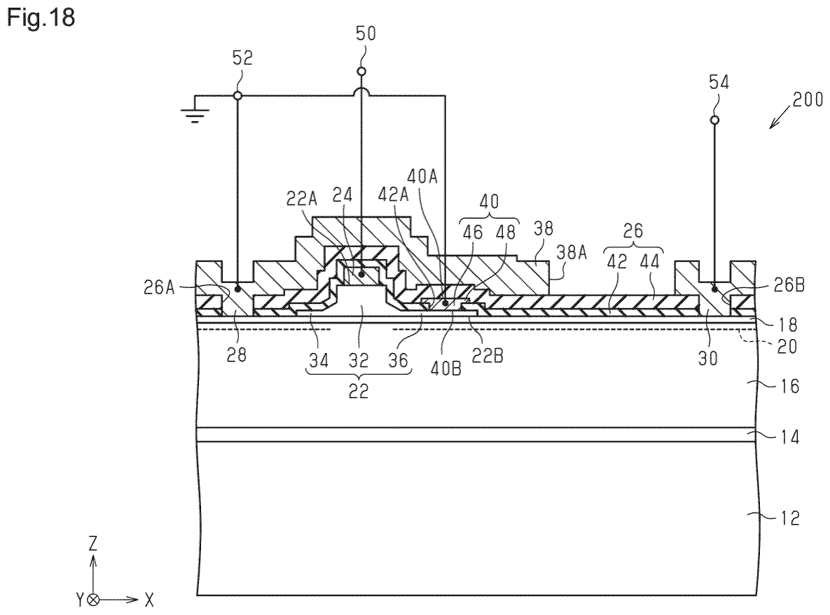

FIG. 18 is a schematic cross-sectional view showing an example of a nitride semiconductor device 200 in a second embodiment. In FIG. 18, the same reference characters are given to those components that are the same as the corresponding components of the nitride semiconductor device 10 shown in FIG. 1. Such components will not be described in detail.

As shown in FIG. 18, the nitride semiconductor device 200 of the second embodiment has a structure similar to that of the nitride semiconductor device 10. The nitride semiconductor device 200 differs from the nitride semiconductor device 10 in that the auxiliary electrode 40 is electrically connected to the source electrode 28. Therefore, the nitride semiconductor device 200 does not necessarily have to include a control terminal such as the control terminal 56 shown in FIG. 1. In the second embodiment, the auxiliary electrode 40 may be used as a second field plate electrode. In other words, the nitride semiconductor device 200 includes the auxiliary electrode 40 used as a second field plate electrode in addition to the field plate electrode 38.

In the nitride semiconductor device 200, the field plate electrode 102 shown in FIG. 17 may be used instead of the field plate electrode 38. In this case, the source electrode 28, the field plate electrode 102, and the auxiliary electrode 40 are separated from each other in the region between the first opening 26A and the second opening 26B and are electrically connected to each other.

Operation

The operation of the nitride semiconductor device 200 of the present embodiment will be described below. When a voltage that is greater than the threshold voltage is applied to the gate electrode 24 of the nitride semiconductor device 200, the 2DEG 20 forms a channel in the electron transit layer 16 and establishes a source-drain connection. In contrast, in the zero bias state, the 2DEG 20 is not formed in at least a portion of the region of the electron transit layer 16 located under the gate layer 22 (refer to FIG. 18). This is because the gate layer 22 contains the acceptor impurity, the energy levels of the electron transit layer 16 and the electron supply layer 18 are raised, and the 2DEG 20 is depleted as a result. This achieves the normally-off operation of the nitride semiconductor device 200.

In the nitride semiconductor device 200, when the source electrode 28 is the reference point and a positive voltage is applied to the drain electrode 30, electrons may be trapped in a region between the gate electrode 24 and the drain electrode 30 (in the present embodiment, in the vicinity of the drain-side extension 36). For example, electrons may be trapped in a defect site (of, for example, the electron supply layer 18) that is formed by processing damage (e.g., etching damage) during the manufacturing of the nitride semiconductor device 200. In addition, when the positive voltage is applied to the drain electrode 30, a potential difference occurs between the gate electrode 24 and the drain electrode 30. As a result, holes may be drawn out of the gate layer 22 from the gate electrode 24. Such electron trapping and hole drawing-out cause variations in the electric potential particularly in the region between the gate electrode 24 and the drain electrode 30. As a result, the gate bias is substantially reduced. This may increase the on-resistance due to, for example, a decrease in the 2DEG 20.

In this regard, the nitride semiconductor device 200 of the present embodiment includes the auxiliary electrode 40, which is formed above the electron supply layer 18 and directly covered by the passivation layer 26. The auxiliary electrode 40 is disposed between the gate electrode 24 and the drain electrode 30 in plan view. The auxiliary electrode 40, disposed between the gate electrode 24 and the drain electrode 30, limits variations in the electric potential in the region between the gate electrode 24 and the drain electrode 30.

As in the present embodiment, in an example in which the auxiliary electrode 40 is electrically connected to the source electrode 28, the trapped electrons escape from the auxiliary electrode 40 to the source electrode 28. This limits variations in the electric potential in the region between the gate electrode 24 and the drain electrode 30.

In addition, the auxiliary electrode 40 is electrically connected to the source electrode 28 and thus is used as a second field plate electrode. This reduces concentration of electric field in the vicinity of the end of the gate electrode 24. Since the auxiliary electrode 40 is located closer to the 2DEG 20 than the field plate electrode 38, variations in the electric potential in the region between the gate electrode 24 and the drain electrode 30 are limited in a more effective manner.

The nitride semiconductor device 200 of the present embodiment has the following advantages.

(2-1) The auxiliary electrode 40 is electrically connected to the source electrode 28. This allows the electrons trapped in the auxiliary electrode 40 to escape to the source electrode 28 and also reduces concentration of the electric field in the vicinity of the end of the gate electrode 24. As a result, variations in the electric potential in the region between the gate electrode 24 and the drain electrode 30 are limited.

In addition, the nitride semiconductor device 200 has advantages similar to the advantages (1-1) to (1-4), (1-6), (1-8), and (1-9) of the nitride semiconductor device 10 described above.

### Modified Example of Gate Layer

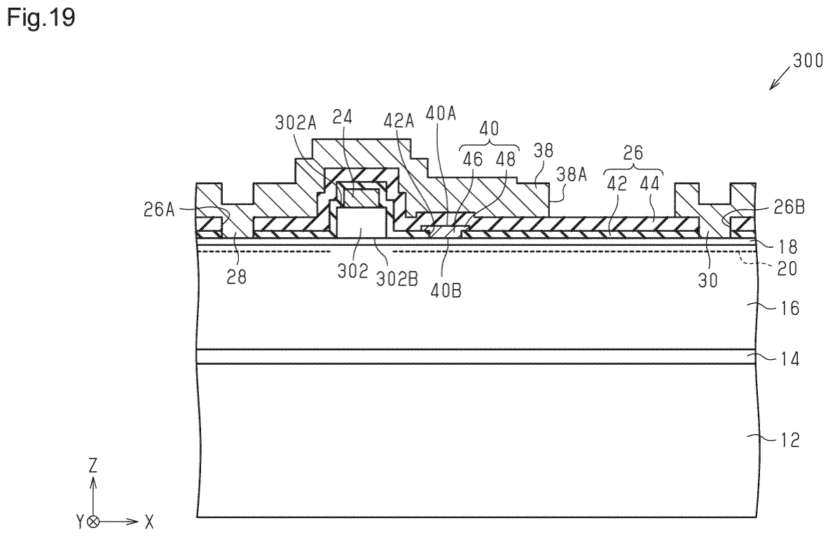

FIG. 19 is a schematic cross-sectional view of an example of a nitride semiconductor device 300 showing a modified example of a gate layer. In FIG. 19, the same reference characters are given to those components that are the same as the corresponding components of the nitride semiconductor device 10 shown in FIG. 1. Such components will not be described in detail.

As shown in FIG. 19, the nitride semiconductor device 300 includes a gate layer 302. The gate layer 302 does not include extensions such as the source-side extension 34 and the drain-side extension 36 shown in FIG. 1. The gate layer 302 corresponds to the gate ridge 32 shown in FIG. 1. The gate layer 302 may include an upper surface 302A on which the gate electrode 24 is formed and a bottom surface 302B that is in contact with the electron supply layer 18.

In the nitride semiconductor device 300, the auxiliary electrode 40 is formed on the electron supply layer 18. Thus, the auxiliary electrode 40 may include an upper surface 40A that is in contact with the passivation layer 26 and a bottom surface 40B that is in contact with the electron supply layer 18.

In the nitride semiconductor device 300, since the auxiliary electrode 40 is in contact with the electron supply layer 18, the distance between the 2DEG 20 and the auxiliary electrode 40 is decreased. In addition, since the auxiliary electrode 40 is in contact with the electron supply layer 18, the electron traps in the electron supply layer 18 are efficiently remedied. In addition, the nitride semiconductor device 300 has advantages similar to the advantages (1-1) and (1-6) to (1-9) of the nitride semiconductor device 10 described above.

As in the first embodiment, the nitride semiconductor device 300 may have an operation mode in which the auxiliary electrode 40 is positively biased with respect to the source electrode 28. In this case, the nitride semiconductor device 300 has an advantage similar to the advantage (1-5) of the nitride semiconductor device 10 described above.

As in the second embodiment, the nitride semiconductor device 300 may include an auxiliary electrode 40 that is electrically connected to the source electrode 28. In this case, the nitride semiconductor device 300 has an advantage similar to the advantage (2-1) of the nitride semiconductor device 200 described above.

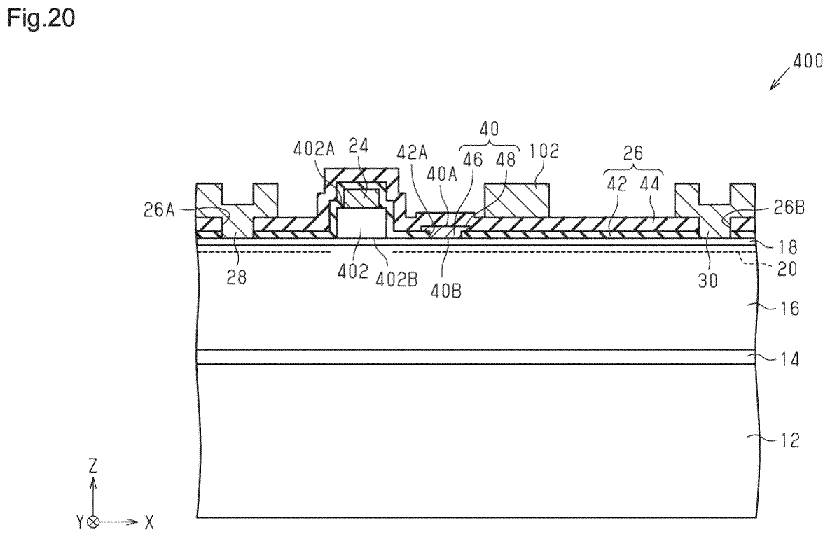

FIG. 20 is a schematic cross-sectional view of an example of a nitride semiconductor device 400 showing a modified example of a gate layer. In FIG. 20, the same reference characters are given to those components that are the same as the corresponding components of the nitride semiconductor device 100 shown in FIG. 17. Such components will not be described in detail.

As shown in FIG. 20, the nitride semiconductor device 400 includes a gate layer 402. The gate layer 402 does not include extensions such as the source-side extension 34 and the drain-side extension 36 shown in FIG. 17. The gate layer 402 corresponds to the gate ridge 32 shown in FIG. 17. The gate layer 402 may include an upper surface 402A on which the gate electrode 24 is formed and a bottom surface 402B that is in contact with the electron supply layer 18.

In the nitride semiconductor device 400, the auxiliary electrode 40 is formed on the electron supply layer 18. Thus, the auxiliary electrode 40 may include an upper surface that is in contact with the passivation layer 26 and a bottom surface 40B that is in contact with the electron supply layer 18.

In the nitride semiconductor device 400, since the auxiliary electrode 40 is in contact with the electron supply layer 18, the distance between the 2DEG 20 and the auxiliary electrode 40 is decreased. In addition, since the auxiliary electrode 40 is in contact with the electron supply layer 18, the electron traps in the electron supply layer 18 are efficiently remedied. In addition, the nitride semiconductor device 400 has advantages similar to the advantages (1-1), (1-6), (1-8), and (1-9) of the nitride semiconductor device described above.

As in the first embodiment, the nitride semiconductor device 400 may have an operation mode in which the auxiliary electrode 40 is positively biased with respect to the source electrode 28. In this case, the nitride semiconductor device 400 has an advantage similar to the advantage (1-5) of the nitride semiconductor device 10 described above. In addition, since the upper surface 40A of the auxiliary electrode 40 does not face the field plate electrode 102, increases in parasitic capacitance between the auxiliary electrode 40 and the field plate electrode 102 are limited.

As in the second embodiment, the nitride semiconductor device 400 may include an auxiliary electrode 40 that is electrically connected to the source electrode 28. In this case, the nitride semiconductor device 400 has an advantage similar to the advantage (2-1) of the nitride semiconductor device 200 described above.

### Other Modified Examples

Each of the embodiments and the modified examples described above may be modified as follows.

The semiconductor package 90 shown in FIG. 16 may include any one of the nitride semiconductor devices 100, 200, 300, and 400, instead of the nitride semiconductor device 10.

The upper surface 40A of each of the auxiliary electrode 40 may be flat or may include a recess.

The first layer 42 and the second layer 44 of the passivation layer 26 may be formed from the same material or different materials. For example, the first layer 42 may be formed from SiN, and the second layer 44 may be formed from Sift.

In the example shown in FIG. 1, the entirety of the bottom surface 40B of the auxiliary electrode 40 does not necessarily have to be in contact with the drain-side extension 36. For example, the bottom surface 40B of the auxiliary electrode 40 may be in contact with the drain-side extension 36 and the electron supply layer 18. More specifically, a portion of the bottom surface 40B may be in contact with the drain-side extension 36, and the remaining portion of the bottom surface 40B may be in contact with the electron supply layer 18.

One or more of the various examples described in this specification may be combined within a range where there is no technical inconsistency.

In this specification, “at least one of A and B” should be understood to mean “only A, or only B, or both A and B”.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer. For example, a structure in which the electron supply layer 18 is formed on the electron transit layer 16 includes a structure in which an intermediate layer is disposed between the electron supply layer 18 and the electron transit layer 16 to stably form the 2DEG 20.

The directional terms used in the present disclosure such as “vertical,” “horizontal,” “above,” “below,” “top,” “bottom,” “front,” “back,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

In an example, the Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

### CLAUSES

The technical aspects that are understood from the present disclosure will hereafter be described. It should be noted that, for the purpose of facilitating understanding with no intention to limit, elements described in clauses are given the reference characters of the corresponding elements of the embodiments. The reference characters used as examples to facilitate understanding, and the elements in each clause are not limited to those elements given with the reference characters.

Clause 1

A nitride semiconductor device, including:
an electron transit layer (16) formed from a nitride semiconductor;
an electron supply layer (18) formed on the electron transit layer (16), the electron supply layer (18) being formed from a nitride semiconductor having a band gap that is larger than that of the electron transit layer (16);
a gate layer (22) formed on the electron supply layer (18), the gate layer (22) being formed from a nitride semiconductor including an acceptor impurity;
a gate electrode (24) formed on the gate layer (22); and
a passivation layer (26) covering the electron supply layer (18), the gate layer (22), and the gate electrode (24), the passivation layer (26) including a first opening (26A) and a second opening (26B) separated from each other in a first direction, the gate layer (22) being disposed between the first opening (26A) and the second opening (26B);
a source electrode (28) in contact with the electron supply layer (18) through the first opening (26A);
a drain electrode (30) in contact with the electron supply layer (18) through the second opening (26B); and
an auxiliary electrode (40) formed above the electron supply layer (18) and directly covered by the passivation layer (26),
wherein the auxiliary electrode (40) is disposed between the gate electrode (24) and the drain electrode (30) in plan view.

Clause 2

The nitride semiconductor device according to clause 1, in which the gate layer (22) includes:
a gate ridge (32) on which the gate electrode (24) is formed;
a source-side extension (34) extending from the gate ridge (32) toward the first opening (26A), the source-side extension (34) being smaller in thickness than the gate ridge (32); and
a drain-side extension (36) extending from the gate ridge (32) toward the second opening (26B), the drain-side extension (36) being smaller in thickness than the gate ridge (32).

Clause 3

The nitride semiconductor device according to clause 2, in which the auxiliary electrode (40) includes an upper surface (40A) in contact with the passivation layer (26) and a bottom surface (40B) in contact with the drain-side extension (36).

Clause 4

The nitride semiconductor device according to clause 2 or 3, in which the drain-side extension (36) is greater in dimension than the source-side extension (34) in the first direction.

Clause 5

The nitride semiconductor device according to clause 1, in which the auxiliary electrode (40) includes an upper surface (40A) in contact with the passivation layer (26) and a bottom surface (40B) in contact with the electron supply layer (18).

Clause 6

The nitride semiconductor device according to any one of clauses 1 to 5, in which the nitride semiconductor device has an operation mode in which the auxiliary electrode (40) is positively biased with respect to the source electrode (28).

Clause 7

The nitride semiconductor device according to any one of clauses 1 to 5, in which the auxiliary electrode (40) is electrically connected to the source electrode (28).

Clause 8

The nitride semiconductor device according to any one of clauses 1 to 7, further including:
a field plate electrode (38; 102) formed on the passivation layer (26) and at least partially extending in a region between the gate layer (22) and the drain electrode (30) in plan view,
wherein the field plate electrode (38; 102) is electrically connected to the source electrode (28).

Clause 9

The nitride semiconductor device according to clause 8, in which
the passivation layer (26) includes a first layer (42) including a third opening (42A) and a second layer (44) formed on the first layer (42), and
the auxiliary electrode (40) includes a base portion (46) embedded in the third opening (42A) of the first layer (42) and an upper portion (48) directly covered by the second layer (44).

Clause 10

The nitride semiconductor device according to clause 9, in which the field plate electrode (38) is continuous with the source electrode (28).

Clause 11

The nitride semiconductor device according to clause 10, in which the auxiliary electrode (40) is separated from the field plate electrode (38) by the second layer (44) of the passivation layer (26).

Clause 12

The nitride semiconductor device according to any one of clauses 9 to 11, in which the second layer (44) is greater in thickness than the first layer (42).

Clause 13

The nitride semiconductor device according to clause 8, in which the field plate electrode (102) is separated from the source electrode (28) in the first direction on the passivation layer (26) between the first opening (26A) and the second opening (26B).

Clause 14

The nitride semiconductor device according to clause 13, in which the field plate electrode (102) is separated from the auxiliary electrode (40) in plan view.

Clause 15

The nitride semiconductor device according to any one of clauses 1 to 14, further comprising:
a connection portion (62) electrically connected to the auxiliary electrode (40) and formed in an inactive region (60) of the nitride semiconductor device.

Clause 16

The nitride semiconductor device according to clause 15, in which
the drain electrode (30) is formed in an active region (58) of the nitride semiconductor device, and
the inactive region (60) is located adjacent to the active region (58) in a second direction orthogonal to the first direction in plan view.

Clause 17

The nitride semiconductor device according to any one of clauses 1 to 16, further including:
a gate terminal (50) electrically connected to the gate electrode (24);
a source terminal (52) electrically connected to the source electrode (28);
a drain terminal (54) electrically connected to the drain electrode (30); and
a control terminal (56) electrically connected to the auxiliary electrode (40).

Clause 18

The nitride semiconductor device according to any one of clauses 1 to 17, wherein
the electron transit layer (16) includes GaN, and
the electron supply layer (18) includes AlₓGa₁₋ₓN, where 0<x<0.3,
the gate layer (22) includes GaN containing at least one of Mg and Zn as an impurity.

Clause 19

The nitride semiconductor device according to clause 2, in which
the drain-side extension (36) has a dimension in the first direction that is greater than or equal to 1 μm, and
the auxiliary electrode (40) has a dimension in the first direction that is greater than or equal to 0.4 μm.

Clause 20

A semiconductor package (90), including:
the nitride semiconductor device (10) according to clause 17;
a drive circuit (92) connected to the nitride semiconductor device; and
a plurality of external terminals (94A, 94B, 94C, 94D, 94E),
wherein the control terminal (56) is connected to the drive circuit (92) and is not directly connected to any of the plurality of external terminals (94A, 94B, 94C, 94D, 94E).

Clause 21

The nitride semiconductor device according to any one of clauses 1 to 19, in which the gate layer (22) is disposed closer to the first opening (26A) than to the second opening (26B).

Clause 22

The nitride semiconductor device according to clause 9, in which the upper portion (48) of the auxiliary electrode (40) is formed in a region greater than the third opening (42A) in plan view.

Clause 23

The nitride semiconductor device according to clause 16, in which a dimension (D2) of the connection portion (62) in the second direction is larger than a dimension (D1) of the auxiliary electrode (40) in the first direction.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer formed from a nitride semiconductor;
an electron supply layer formed on the electron transit layer, the electron supply layer being formed from a nitride semiconductor having a band gap that is larger than that of the electron transit layer;
a gate layer formed on the electron supply layer, the gate layer being formed from a nitride semiconductor including an acceptor impurity;
a gate electrode formed on the gate layer; and
a passivation layer covering the electron supply layer, the gate layer, and the gate electrode, the passivation layer including a first opening and a second opening separated from each other in a first direction, the gate layer being disposed between the first opening and the second opening;
a source electrode in contact with the electron supply layer through the first opening;
a drain electrode in contact with the electron supply layer through the second opening; and
an auxiliary electrode formed above the electron supply layer and directly covered by the passivation layer,
wherein the auxiliary electrode is disposed between the gate electrode and the drain electrode in plan view.

2. The nitride semiconductor device according to claim 1, wherein the gate layer includes:
a gate ridge on which the gate electrode is formed;
a source-side extension extending from the gate ridge toward the first opening, the source-side extension being smaller in thickness than the gate ridge; and
a drain-side extension extending from the gate ridge toward the second opening, the drain-side extension being smaller in thickness than the gate ridge.

3. The nitride semiconductor device according to claim 2, wherein the auxiliary electrode includes an upper surface in contact with the passivation layer and a bottom surface in contact with the drain-side extension.

4. The nitride semiconductor device according to claim 2, wherein the drain-side extension is greater in dimension than the source-side extension in the first direction.

5. The nitride semiconductor device according to claim 1, wherein the auxiliary electrode includes an upper surface in contact with the passivation layer and a bottom surface in contact with the electron supply layer.

6. The nitride semiconductor device according to claim 1, wherein the nitride semiconductor device has an operation mode in which the auxiliary electrode is positively biased with respect to the source electrode.

7. The nitride semiconductor device according to claim 1, wherein the auxiliary electrode is electrically connected to the source electrode.

8. The nitride semiconductor device according to claim 1, further comprising:
a field plate electrode formed on the passivation layer and at least partially extending in a region between the gate layer and the drain electrode in plan view,
wherein the field plate electrode is electrically connected to the source electrode.

9. The nitride semiconductor device according to claim 8, wherein
the passivation layer includes a first layer including a third opening and a second layer formed on the first layer, and
the auxiliary electrode includes a base portion embedded in the third opening of the first layer and an upper portion directly covered by the second layer.

10. The nitride semiconductor device according to claim 9, wherein the field plate electrode is continuous with the source electrode.

11. The nitride semiconductor device according to claim 10, wherein the auxiliary electrode is separated from the field plate electrode by the second layer of the passivation layer.

12. The nitride semiconductor device according to claim 11, wherein the second layer is greater in thickness than the first layer.

13. The nitride semiconductor device according to claim 8, wherein the field plate electrode is separated from the source electrode in the first direction on the passivation layer between the first opening and the second opening.

14. The nitride semiconductor device according to claim 13, wherein the field plate electrode is separated from the auxiliary electrode in plan view.

15. The nitride semiconductor device according to claim 1, further comprising:
a connection portion electrically connected to the auxiliary electrode and formed in an inactive region of the nitride semiconductor device.

16. The nitride semiconductor device according to claim 15, wherein
the drain electrode is formed in an active region of the nitride semiconductor device, and
the inactive region is located adjacent to the active region in a second direction orthogonal to the first direction in plan view.

17. The nitride semiconductor device according to claim 1, further comprising:
a gate terminal electrically connected to the gate electrode;
a source terminal electrically connected to the source electrode;
a drain terminal electrically connected to the drain electrode; and
a control terminal electrically connected to the auxiliary electrode.

18. The nitride semiconductor device according to claim 1, wherein
the electron transit layer includes GaN, and
the electron supply layer includes AlₓGa₁₋ₓN, where 0<x<0.3, and
the gate layer includes GaN containing at least one of Mg and Zn as an impurity.

19. The nitride semiconductor device according to claim 2, wherein
the drain-side extension has a dimension in the first direction that is greater than or equal to 1 μm, and
the auxiliary electrode has a dimension in the first direction that is greater than or equal to 0.4 μm.

20. A semiconductor package, comprising:
the nitride semiconductor device according to claim 17;
a drive circuit connected to the nitride semiconductor device; and
a plurality of external terminals,
wherein the control terminal is connected to the drive circuit and is not directly connected to any of the plurality of external terminals.
